(19) United States
(12) Patent Application Publication
(10) Pub. No.: US 2021/0359686 A1
(43) Pub. Date: Nov. 18, 2021

(54) CLOCKED LATCH CIRCUIT AND A CLOCK GENERATING CIRCUIT USING THE SAME

(71) Applicant: SK hynix Inc., Icheon-si Gyeonggi-do (KR)

(72) Inventor: Ji Hyo KANG, Icheon-si Gyeonggi-do (KR)

(73) Assignee: SK hynix Inc., Icheon-si Gyeonggi-do (KR)

(21) Appl. No.: 17/034,796

(22) Filed: Sep. 28, 2020

(30) Foreign Application Priority Data
May 15, 2020 (KR) 10-2020-0058177

(51) Int. Cl. H03K 19/096; H03K 19/17784; H03K 19/0185; H03K 3/356

(52) U.S. Cl. CPC H03K 19/0963; H03K 3/356121; H03K 19/018571; H03K 19/17784

(57) ABSTRACT

A clocked latch circuit includes an amplification circuit, a latch circuit, a first current source, and a second current source. The amplification circuit changes voltage levels of first and second output signals based on a clock signal, a first input signal, and a second input signal. The latch circuit maintains the voltage levels of the first and second output signals based on a complementary signal of the clock signal. The first current source allows a first current to flow to activate the amplification circuit. The second current source allows a second current that is different from the first current to flow to activate the latch circuit.

### CROSS-REFERENCES TO RELATED APPLICATION

The present application claims priority under 35 U.S.C. § 119(a) to Korean application number 10-2020-0058177, filed on May 15, 2020, in the Korean Intellectual Property Office, which is incorporated herein by reference in its entirety as set forth in full.

### BACKGROUND

### 1. Technical Field

Various embodiments are related to an integrated circuit, and more particularly, to a clocked latch circuit and a clock generating circuit using the same.

### 2. Related Art

An electronic device includes a lot of electronic elements, and a computer system includes a lot of semiconductor apparatuses, each comprising a semiconductor. Semiconductor apparatuses configuring a computer system may communicate with each other by receiving and transmitting data and a clock signal. The semiconductor apparatus may include a clocked latch circuit in order to amplify an input signal and latch the amplified signal. In synchronization with a clock signal, the clocked latch circuit may amplify the input signal to generate an output signal and may maintain a voltage level of the output signal. For example, the clocked latch circuit may amplify the input signal to change the voltage level of the output signal when the clock signal has a logic high level. For example, the clocked latch circuit may maintain the voltage level of the output signal when the clock signal has a logic low level.

As the operation speed of the computer system increases, the frequency of the clock signal increases, and the amplitude of the clock signal becomes smaller. Also, the swing width of the input signal becomes smaller. When the amplitudes of the input signal and the clock signal becomes smaller, the size of a transistor within the clocked latch circuit should be adjusted in order for the clocked latch circuit to precisely amplify the input signal. However, when the size of the transistor is adjusted, there may be a risk that the operational frequency range of the clocked latch circuit is limited.

### SUMMARY

In an embodiment, a clocked latch circuit may include an amplification circuit, a latch circuit, a first current source and a second current source. The amplification circuit may be coupled to a first output node, a second output node, and a first node. The amplification circuit may change voltage levels of the first output node and the second output node based on a clock signal, a first input signal, and a second input signal. The first output node and the second output node may be coupled to a node to which a first power voltage is supplied. The latch circuit may be coupled to the first output node, the second output node, and a second node. The latch circuit may maintain the voltage levels of the first output node and the second output node based on a complementary signal of the clock signal. The first current source may output a first current to flow from the first node to a node to which a second power voltage is supplied. The second current source may output a second current to flow from the second node to the node to which the second power voltage is supplied. The second current may be different from the first current.

In an embodiment, a clocked latch circuit may include an amplification circuit, a latch circuit, a first activation circuit, and a second activation circuit. The amplification circuit may be coupled between a first common node and a node to which a first power voltage is supplied. The amplification circuit may change voltage levels of a first output node and a second output node based on a first input signal and a second input signal. The latch circuit may be coupled between a second common node and the node to which the first power voltage is supplied. The latch circuit may maintain the voltage levels of the first output node and the second output node based on the voltage levels of the first output node and the second output node. The first activation circuit may output a first current to flow from the first common node to a node to which a second power voltage is supplied based on a clock signal. The second activation circuit may output a second current to flow from the second common node to the node to which the second power voltage is supplied based on the clock signal. The second current may be different from the first current.

In an embodiment, a clock generating circuit may include a first amplification circuit, a first latch circuit, a second amplification circuit, a second latch circuit, a first current source, and a second current source. The first amplification circuit may be coupled between a first node and a node to which a first power voltage is supplied. The first amplification circuit may output a second clock signal and a fourth clock signal through a first output node and a second output node based on a first control clock signal, a first clock signal, and a third clock signal. The first latch circuit may be coupled between a second node and the node to which the first power voltage is supplied. The first latch circuit may maintain voltage levels of the first output node and the second output node based on a second control clock signal. The second amplification circuit may be coupled between the first node and the node to which the first power voltage is supplied. The second amplification circuit may output the first clock signal and the third clock signal through a third output node and a fourth output node based on the second control clock signal, the second clock signal, and the fourth clock signal. The second latch circuit may be coupled between the second node and the node to which the first power voltage is supplied. The second latch circuit may maintain voltage levels of the third output node and the fourth output node based on the first control clock signal. The first current source may output a first current to flow from the first node to a node to which a second power voltage is supplied. The second current source may output a second current to flow from the second node to the node to which the second power voltage is supplied. The second current may be different from the first current.

In an embodiment, a clock generating circuit may include a first amplification circuit, a first latch circuit, a second amplification circuit, a second latch circuit, a first activation circuit, and a second activation circuit. The first amplification circuit may be coupled between a first common node and a node to which a first power voltage is supplied. The first amplification circuit may output a second clock signal and a fourth clock signal through a first output node and a second output node based on a first clock signal and a third clock signal. The first latch circuit may be coupled between a second common node and the node to which the first power voltage is supplied. The first latch circuit may maintain voltage levels of the first output node and the second output node. The second amplification circuit may be coupled between a third common node and the node to which the first power voltage is supplied. The second amplification circuit may output the first clock signal and the third clock signal through a third output node and a fourth output node based on the second clock signal and the fourth clock signal. The second latch circuit may be coupled between a fourth common node and the node to which the first power voltage is supplied. The second latch circuit may maintain voltage levels of the third output node and the fourth output node. The first activation circuit may output a first current to flow from the first common node to a node to which a second power voltage is supplied, based on a first control clock signal and may output the first current to flow from the third common node to the node to which the second power voltage is supplied based on a second control clock signal. The second activation circuit may output a second current to flow from the second common node to the node to which the second power voltage is supplied based on the second control clock signal and may output the second current to flow from the fourth common node to the node to which the second power voltage is supplied based on the first control clock signal.

### BRIEF DESCRIPTION OF THE DRAWINGS

FIG. 1 is a diagram, illustrating a configuration of a clocked latch circuit in accordance with an embodiment.

FIG. 2 is a diagram, illustrating a configuration of a clocked latch circuit in accordance with an embodiment.

FIGS. 3A and 3B are diagrams, illustrating configurations reset circuits in accordance with an embodiment.

FIG. 4 is a timing diagram, illustrating waveforms of an output signal, generated from a clocked latch circuit, in accordance with an embodiment and an output signal, generated from a conventional clocked latch circuit.

FIG. 5 is a timing diagram, illustrating waveforms of an output signal, generated from a clocked latch circuit, in accordance with an embodiment and an output signal, generated from a conventional clocked latch circuit.

FIG. 6 is a timing diagram, illustrating waveforms of an output signal, generated from a clocked latch circuit, in accordance with an embodiment and an output signal, generated from a conventional clocked latch circuit.

FIG. 7 is a diagram, illustrating a configuration of a clock generating circuit in accordance with an embodiment.

FIG. 8 is a diagram, illustrating a configuration of a clock generating circuit in accordance with an embodiment.

FIG. 9 is a timing diagram, illustrating an operation of a clock generating circuit in accordance with an embodiment.

FIG. 10 is a timing diagram, illustrating waveforms of an output signal, generated from a clock generating circuit, in accordance with an embodiment and an output signal, generated from a conventional clock generating circuit.

FIG. 11 is a diagram, illustrating a configuration of a semiconductor system in accordance with an embodiment.

### DETAILED DESCRIPTION

Various examples and implementations of the disclosed technology are described below with reference to the accompanying drawings.

It will be understood that although the terms “first”, “second”, “third” etc. are used herein to describe various elements, these elements should not be limited by these terms. These terms are only used to distinguish one element from another element. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

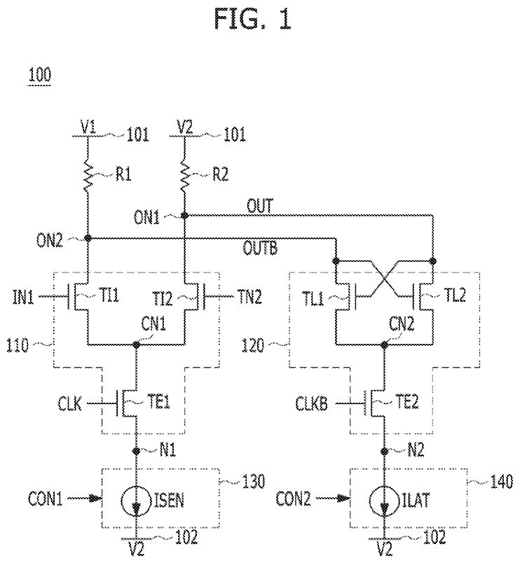

FIG. 1 is a diagram, illustrating a configuration of a clocked latch circuit 100 in accordance with an embodiment. Referring to FIG. 1, the clocked latch circuit 100 may receive a clock signal CLK, a first input signal IN1 and a second input signal IN2 to generate a first output signal OUT and a second output signal OUTB. The clocked latch circuit 100 may sequentially perform an amplification operation and a latch operation based on the clock signal CLK. Based on the clock signal CLK, the clocked latch circuit 100 may differentially amplify the first input signal IN1 and the second input signal IN2 to change voltage levels of the first output signal OUT and the second output signal OUTB. Based on a complementary signal CLKB of the clock signal CLK, the clocked latch circuit 100 may maintain the voltage levels of the first output signal OUT and the second output signal OUTB. In an embodiment, the first input signal IN1 and the second input signal IN2 may be a pair of differential signals. The second input signal IN2 may be a complementary signal with a complementary voltage level to the first input signal IN1. In an embodiment, the first input signal IN1 may be a single-ended signal and the second input signal IN2 may have a reference voltage. The reference voltage may correspond to a middle of a swing range of the first input signal IN1.

The clocked latch circuit 100 may include an amplification circuit 110, a latch circuit 120, a first current source 130, and a second current source 140. Based on the first input signal IN1 and the second input signal IN2, the amplification circuit 110 may change the voltage levels of the first output signal OUT and the second output signal OUTB. Based on the first input signal IN1, the amplification circuit 110 may change the voltage level of the second output signal OUTB. Based on the second input signal IN2, the amplification circuit 110 may change the voltage level of the first output signal OUT. The amplification circuit 110 may be coupled to a first output node ON1, a second output node ON2, and a first node N1. The first output node ON1 and the second output node ON2 may be a node 101 to which a first power voltage V1 is supplied. The first output signal OUT may be output from the first output node ON1, and the second output signal OUTB may be output from the second output node ON2. The amplification circuit 110 may be activated based on the clock signal CLK. In synchronization with the clock signal CLK, the amplification circuit 110 may amplify the first input signal IN1 and the second input signal IN2 to change the voltage levels of the first output node ON1 and the second output node ON2. When the clock signal CLK has a logic high level, the amplification circuit 110 may change the voltage level of the second output node ON2 based on the voltage level of the first input signal IN1 and may change the voltage level of the first output node ON1 based on the voltage level of the second input signal IN2. When the clock signal CLK has a logic low level, the amplification circuit 110 may be deactivated.

The clocked latch circuit 100 may further include a first load resistor R1 and a second load resistor R2. The second output node ON2 may be coupled to the node 101 to which the first power voltage V1 is supplied through the first load resistor R1. The first output node ON1 may be coupled to the node 101 to which the first power voltage V1 is supplied through the second load resistor R2. The first load resistor R1 and the second load resistor R2 may have the same resistance value. In an embodiment, the second load resistor R2 may have a different resistance value than the first load resistor R1.

The latch circuit 120 may be activated based on the complementary signal CLKB of the clock signal CLK. In synchronization with the complementary signal CLKB of the clock signal CLK, the latch circuit 120 may maintain the voltage levels of the first output signal OUT and the second output signal OUTB. When the complementary signal CLKB of the clock signal CLK has a logic high level, the latch circuit 120 may maintain the voltage levels of the first output signal OUT and the second output signal OUTB. The latch circuit 120 may maintain the voltage level of the second output signal OUTB based on the voltage level of the first output signal OUT. The latch circuit 120 may maintain the voltage level of the first output signal OUT based on the voltage level of the second output signal OUTB. The latch circuit 120 may be coupled to the first output node ON1, the second output node ON2, and a second node N2. In synchronization with the complementary signal CLKB of the clock signal CLK, the latch circuit 120 may maintain the voltage levels of the first output node ON1 and the second output node ON2. The latch circuit 120 may maintain the voltage level of the second output node ON2 based on the voltage level of the first output node ON1. The latch circuit 120 may maintain the voltage level of the first output node ON1 based on the voltage level of the second output node ON2.

The first current source 130 may allow a first current ISEN to flow from the amplification circuit 110 in order to activate the amplification circuit 110. The first current source 130 may allow the first current ISEN to flow through the first node N1. The first current source 130 may be coupled between the first node N1 and a node 102 to which a second power voltage V2 is supplied. The first current source 130 may allow the first current ISEN to flow from the first node N1 to the node 102 to which the second power voltage V2 is supplied. The second power voltage V2 may have a lower voltage level than the first power voltage V1.

The second current source 140 may allow a second current ILAT to flow from the latch circuit 120 in order to activate the latch circuit 120. The second current source 140 may allow the second current ILAT to flow through the second node N2. The second current source 140 may be coupled between the second node N2 and the node 102 to which the second power voltage V2 is supplied. The second current source 140 may allow the second current ILAT to flow from the second node N2 to the node 102 to which the second power voltage V2 is supplied. The second current ILAT may be different from the first current ISEN. In an embodiment, the second current ILAT may be greater than the first current ISEN.

The first current source 130 may further receive a first current control signal CON1. The first current source 130 may be a variable current source configured to change an amount of the first current ISEN based on the first current control signal CON1. The second current source 140 may further receive a second current control signal CON2. The second current source 140 may be a variable current source configured to change an amount of the second current ILAT based on the second current control signal CON2. The first current control signal CON1 and the second current control signal CON2 may be digital code signals each with a plurality of bits. The first current control signal CON1 and the second current control signal CON2 may be analogue voltage signals with various voltage levels.

The amplification circuit 110 may include a first input transistor TI1, a second input transistor TI2, and a first enable transistor TE1. Each of the first input transistor TI1, the second input transistor TI2, and the first enable transistor TE1 may be a N-channel MOS transistor. The first input transistor TI1 may couple the second output node ON2 to a first common node CN1 based on the first input signal IN1. The first input transistor TI1 may be coupled to the second output node ON2 and the first common node CN1 at its drain and source, respectively, and may receive the first input signal IN1 at its gate. When the first input signal IN1 has a logic high level, the first input transistor TI1 may couple the second output node ON2 to the first common node CN1. When the first input signal IN1 has a logic low level, the first input transistor TI1 may electrically isolate the second output node ON2 from the first common node CN1. The second input transistor TI2 may couple the first output node ON1 to the first common node CN1 based on the second input signal IN2. The second input transistor TI2 may be coupled to the first output node ON1 and the first common node CN1 at its drain and source, respectively, and may receive the second input signal IN2 at its gate. When the second input signal IN2 has a logic high level, the second input transistor TI2 may couple the first output node ON1 to the first common node CN1. When the second input signal IN2 has a logic low level, the second input transistor TI2 may electrically isolate the first output node ON1 from the first common node CN1. The first enable transistor TE1 may couple the first common node CN1 to the first node N1 based on the clock signal CLK. The first enable transistor TE1 may be coupled to the first common node CN1 and the first node N1 at its drain and source, respectively, and may receive the clock signal CLK at its gate. When the clock signal CLK has a logic high level, the first enable transistor TE1 may couple the first common node CN1 to the first node N1. When the clock signal CLK has a logic low level, the first enable transistor TE1 may electrically isolate the first common node CN1 from the first node N1.

The latch circuit 120 may include a first latch transistor TL1, a second latch transistor TL2 and a second enable transistor TE2. Each of the first latch transistor TL1, the second latch transistor TL2 and the second enable transistor TE2 may be a N-channel MOS transistor. The first latch transistor TL1 may couple the second output node ON2 to a second common node CN2 based on the voltage level(s) of the first output node ON1 and/or the first output signal OUT. The first latch transistor TL1 may be coupled to the second output node ON2 and the second common node CN2 at its drain and source, respectively, and may be coupled to the first output node ON1 at its gate to receive the first output signal OUT. When the voltage level(s) of the first output node ON1 and/or the first output signal OUT has a logic high level, the first latch transistor TL1 may couple the second output node ON2 to the second common node CN2. When the voltage level(s) of the first output node ON1 and/or the first output signal OUT has a logic low level, the first latch transistor TL1 may electrically isolate the second output node ON2 from the second common node CN2. The second latch transistor TL2 may couple the first output node ON1 to the second common node CN2 based on the voltage level(s) of the second output node ON2 and/or the second output signal OUTB. The second latch transistor TL2 may be coupled to the first output node ON1 and the second common node CN2 at its drain and source, respectively, and may be coupled to the second output node ON2 at its gate to receive the second output signal OUTB. When the voltage level(s) of the second output node ON2 and/or the second output signal OUTB have a logic high level, the second latch transistor TL2 may couple the first output node ON1 to the second common node CN2. When the voltage level(s) of the second output node ON2 and/or the second output signal OUTB have a logic low level, the second latch transistor TL2 may electrically isolate the first output node ON1 from the second common node CN2. The second enable transistor TE2 may couple the second common node CN2 to the second node N2 based on the complementary signal CLKB of the clock signal CLK. The second enable transistor TE2 may be coupled to the second common node CN2 and the second node N2 at its drain and source, respectively, and may receive the complementary signal CLKB of the clock signal CLK at its gate. When the complementary signal CLKB of the clock signal CLK has a logic high level, the second enable transistor TE2 may couple the second common node CN2 to the second node N2. When the complementary signal CLKB of the clock signal CLK has a logic low level, the second enable transistor TE2 may electrically isolate the second common node CN2 from the second node N2.

In an embodiment, the amplification circuit 110 may be configured by the first input transistor TI1 and the second input transistor TI2. The first enable transistor TE1 and the first current source 130 may be combined to configure a first activation circuit. Therefore, the amplification circuit 110 may be modified to be coupled to the first output node ON1, the second output node ON2 and the first common node CN1. The first activation circuit may allow the first current ISEN to flow from the first common node CN1 to the node 102 to which the second power voltage V2 is supplied based on the clock signal CLK to activate the amplification circuit 110. In an embodiment, the latch circuit 120 may be configured by the first latch transistor TL1 and the second latch transistor TL2. The second enable transistor TE2 and the second current source 140 may be combined to configure a second activation circuit. Therefore, the latch circuit 120 may be modified to be coupled to the first output node ON1, the second output node ON2 and the second common node CN2. The second activation circuit may allow the second current ILAT to flow from the second common node CN2 to the node 102 to which the second power voltage V2 is supplied based on the complementary signal CLKB of the clock signal CLK to activate the latch circuit 120.

Describe as follows will be an operation of the clocked latch circuit 100 in accordance with an embodiment. It is assumed that the first input signal IN1 has a logic high level and the second input signal IN2 has a logic low level. When the clock signal CLK has a logic high level, the complementary signal CLKB of the clock signal CLK may have a logic low level. Accordingly, the amplification circuit 110 may be activated and the latch circuit 120 may be deactivated. Based on the first input signal IN1 with a logic high level, the amplification circuit 110 may couple the second output node ON2 to the first node N1 and may change the voltage level of the second output node ON2 to a logic low level. Based on the second input signal IN2 with a logic low level, the amplification circuit 110 may electrically isolate the first output node ON1 from the first node N1 and the voltage level of the first output node ON1 may become a logic high level. Therefore, the first output signal OUT with a logic high level may be output from the first output node ON1 and the second output signal OUTB with a logic low level may be output from the second output node ON2.

When the clock signal CLK transitions from a logic high level to a logic low level, the complementary signal CLKB of the clock signal CLK may transition from a logic low level to a logic high level. Accordingly, the amplification circuit 110 may be deactivated and the latch circuit 120 may be activated. Based on the first output signal OUT with a logic high level, the latch circuit 120 may couple the second output node ON2 to the second node N2 and may maintain the voltage level of the second output node ON2 at a logic low level. Based on the second output signal OUTB with a logic low level, the latch circuit 120 may electrically isolate the first output node ON1 from the second node N2 and may maintain the voltage level of the first output node ON1 at a logic high level. Therefore, the first output signal OUT may have a logic high level for a single period of the clock signal CLK and the second output signal OUTB may have a logic low level for the single period of the clock signal CLK. When the clock signal CLK transitions from a logic low level to a logic high level, the amplification circuit 110 may be activated. The amplification circuit 110 may change the voltage levels of the first output signal OUT and the second output signal OUTB based on the logic levels of the first input signal IN1 and the second input signal IN2. Whenever the clock signal CLK toggles, the amplification circuit 110 and the latch circuit 120 may be alternately activated and the clocked latch circuit 100 may alternately perform the amplification operation and the latch operation.

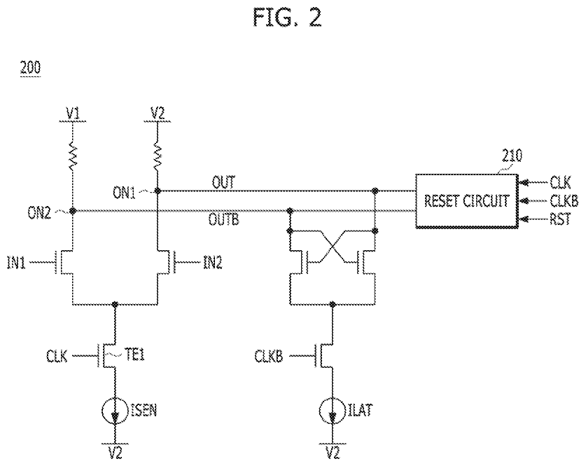

FIG. 2 is a diagram, illustrating a configuration of a clocked latch circuit 200 in accordance with an embodiment. Referring to FIG. 2, the clocked latch circuit 200 may have the same configuration as the clocked latch circuit 100 illustrated in FIG. 1 and may further include a reset circuit 210. Reference numerals of the same elements between the clocked latch circuit 200 and the clocked latch circuit 100 are not illustrated in FIG. 2 and description for the same elements is omitted. The reset circuit 210 may receive the clock signal CLK, the complementary signal CLKB of the clock signal CLK and a reset signal RST. The reset circuit 210 may change the voltage levels of the first output node ON1 and the second output node ON2 based on the clock signal CLK, the complementary signal CLKB of the clock signal CLK and the reset signal RST. The reset circuit 210 may change the voltage levels of the first output node ON1 and the second output node ON2 to set initial voltage levels of the first output node ON1 and the second output node ON2. When the reset signal RST is enabled, the reset circuit 210 may change the voltage level(s) of the second output node ON2 and/or the second output signal OUTB based on the clock signal CLK. When the reset signal RST is enabled, the reset circuit 210 may change the voltage level(s) of the first output node ON1 and/or the first output signal OUT based on the complementary signal CLKB of the clock signal CLK. In a case that the voltage level of the first output node ON1 is set to a logic low level, the voltage level of the second output node ON2 is set to a logic high level. In a case that the voltage level of the first output node ON1 is set to a logic high level, the voltage level of the second output node ON2 is set to a logic low level. When the clocked latch circuit 200 is not in operation (i.e., when the clock signal CLK does not toggle), the voltage levels of the first output node ON1 and the second output node ON2 might not be defined. When the clock signal CLK and the complementary signal CLKB of the clock signal CLK start toggling and thus, the clocked latch circuit 200 becomes in operation, the clocked latch circuit 200 might not precisely generate the first output signal OUT and the second output signal OUTB based on the voltage levels of the first input signal IN1 and the second input signal IN2 if the voltage levels of the first output node ON1 and the second output node ON2 are not defined. For example, the first output signal OUT and the second output signal OUTB may be in a meta-stable state and thus, might not swing between the voltage levels of the first power voltage V1 and the second power voltage V2 but may have small swing widths. Further, in the worst case, the voltage levels of the first output signal OUT and the second output signal OUTB may be switched. The reset circuit 210 may set the initial voltage levels of the first output node ON1 and the second output node ON2 based on the clock signal CLK, the complementary signal CLKB of the clock signal CLK and the reset signal RST. When the initial voltage levels of the first output node ON1 and the second output node ON2 are set, the clocked latch circuit 200 may precisely generate the first output signal OUT and the second output signal OUTB that correspond to the logic levels of the first input signal IN1 and the second input signal IN2 even in an initial phase of an operation.

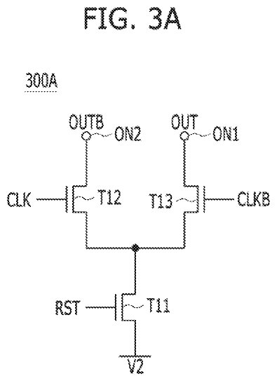

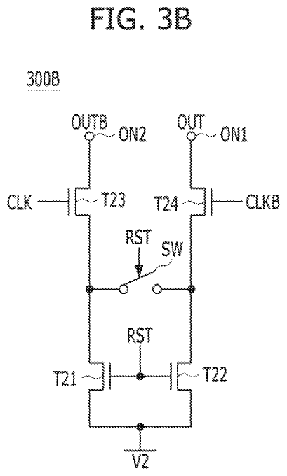

FIGS. 3A and 3B are diagrams, illustrating configurations reset circuits in accordance with an embodiment. Reset circuits 300A and 300B illustrated in FIGS. 3A and 3B may be applied as the reset circuit 210 illustrated in FIG. 2. Referring to FIG. 3A, the reset circuit 300A may include a first transistor T11, a second transistor T12 and a third transistor T13. Each of the first transistor T11, the second transistor T12 and the third transistor T13 may be a N-channel MOS transistor. The first transistor T11 may be coupled to the node 102 to which the second power voltage V2 is supplied at its source and may receive the reset signal RST at its gate. The second transistor T12 may be coupled to the second output node ON2 at its drain, may be coupled to a drain of the first transistor T11 at its source and may receive the clock signal CLK at its gate. The third transistor T13 may be coupled to the first output node ON1 at its drain, may be coupled to the drain of the first transistor T11 at its source and may receive the complementary signal CLKB of the clock signal CLK at its gate. When the reset signal RST is enabled, the first transistor T11 may couple the sources of the second transistor T12 and the third transistor T13 to the node 102 to which the second power voltage V2 is supplied. When the clock signal CLK has a logic high level, the second transistor T12 may couple the second output node ON2 to the node 102 to which the second power voltage V2 is supplied to change the voltage level of the second output signal OUTB to a logic low level. When the complementary signal CLKB of the clock signal CLK has a logic high level, the third transistor T13 may couple the first output node ON1 to the node 102 to which the second power voltage V2 is supplied to change the voltage level of the first output signal OUT to a logic low level.

Referring to FIG. 3B, the reset circuit 300B may include a first transistor T21, a second transistor T22, a switch SW, a third transistor T23 and a fourth transistor T24. Each of the first to fourth transistors T21, T22, T23 and T24 may be a N-channel MOS transistor. The first transistor T21 may be coupled to the node 102 to which the second power voltage V2 is supplied at its source and may receive the reset signal RST at its gate. The second transistor T22 may be coupled to the node 102 to which the second power voltage V2 is supplied at its source and may receive the reset signal RST at its gate. The switch SW may be coupled between drains of the first transistor T21 and the second transistor T22. The switch SW may couple the drain of the first transistor T21 to the drain of the second transistor T22 based on the reset signal RST. For example, when the reset signal RST is enabled, the switch SW may couple the drain of the first transistor T21 to the drain of the second transistor T22. The third transistor T23 may be coupled to the second output node ON2 at its drain, may be coupled to the drain of the first transistor T21 at its source and may receive the clock signal CLK at its gate. The fourth transistor T24 may be coupled to the first output node ON1 at its drain, may be coupled to the drain of the second transistor T22 at its source and may receive the complementary signal CLKB of the clock signal CLK at its gate. When the reset signal RST is enabled, the first transistor T21, the second transistor T22 and the switch SW may be turned on and the sources of the third transistor T23 and the fourth transistor T24 may be coupled to the node 102 to which the second power voltage V2 is supplied. When the clock signal CLK has a logic high level, the third transistor T23 may couple the second output node ON2 to the node 102 to which the second power voltage V2 is supplied to change the voltage level of the second output signal OUTB to a logic low level. When the complementary signal CLKB of the clock signal CLK has a logic high level, the fourth transistor T24 may couple the first output node ON1 to the node 102 to which the second power voltage V2 is supplied to change the voltage level of the first output signal OUT to a logic low level.

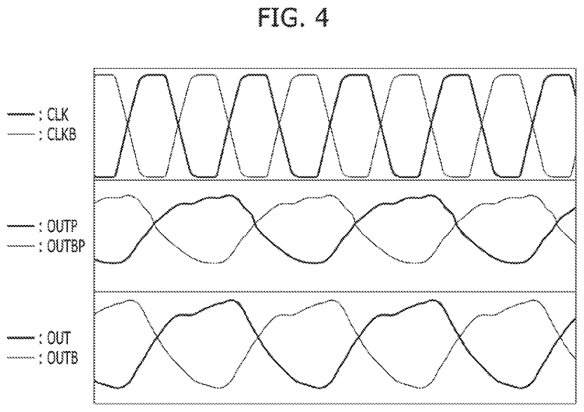

FIG. 4 is a timing diagram, illustrating an output signal, generated from a clocked latch circuit, in accordance with an embodiment and an output signal, generated from a conventional clocked latch circuit. Referring to FIGS. 1, 2 and 4, when the clock signal CLK and the complementary signal CLKB of the clock signal CLK toggle, a first output signal OUTP and a second output signal OUTBP may be generated from the conventional clocked latch circuit and the first output signal OUT and the second output signal OUTB may be generated from the clocked latch circuit 200. Within the conventional clock latch circuit, the first current ISEN and the second current ILAT may have the same as each other. Amounts of the first current ISEN and the second current ILAT may be fixed. Within the clocked latch circuit 200, the first current ISEN and the second current ILAT may vary. The second current ILAT may be greater than the first current ISEN. When the second current ILAT is greater than the first current ISEN, the drivability of the latch circuit 120 may be strengthened and thus, the swing widths of the first output signal OUT and the second output signal OUTB may be increased. Accordingly, the first output signal OUT and the second output signal OUTB output from the clocked latch circuit 200 may have greater amplitudes and greater swing widths than the first output signal OUTP and the second output signal OUTBP output from the conventional clocked latch circuit.

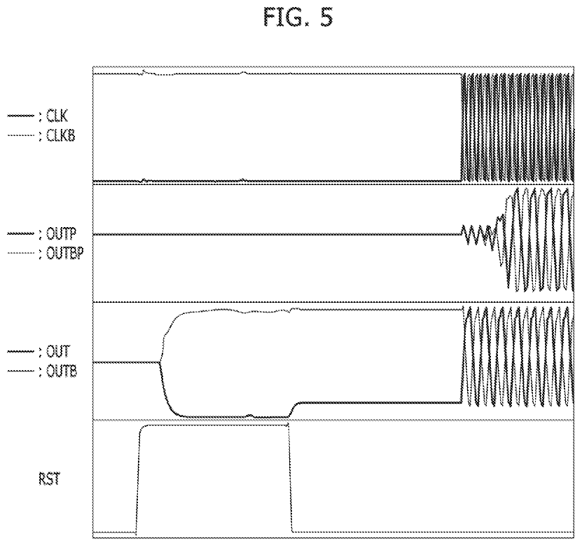

FIG. 5 is a timing diagram, illustrating waveforms of an output signal, generated from a clocked latch circuit, in accordance with an embodiment and an output signal, generated from a conventional clocked latch circuit. Referring to FIGS. 2 and 5, the conventional clocked latch circuit does not include the reset circuit 210 and thus, the voltage level of the first output signal OUTP and the second output signal OUTBP might not be defined while the clock signal CLK and the complementary signal CLKB of the clock signal CLK do not toggle. Accordingly, when the clock signal CLK and the complementary signal CLKB of the clock signal CLK start toggling, the first output signal OUTP and the second output signal OUTBP might not be normally swing and may be in the meta-stable state. When the first output signal OUTP and the second output signal OUTBP are not normally generated, the operational reliability of the conventional clocked latch circuit may be decreased and there may occur a malfunction of an internal circuit using the clock signals generated from the conventional clocked latch circuit. In order to solve the above problem, the clocked latch circuit 200 may include the reset circuit 210 in accordance with an embodiment. When the reset signal RST is enabled, the reset circuit 210 may set the voltage level of the first output signal OUT to a logic low level and may set the voltage level of the second output signal OUTB to a logic high level. Accordingly, when the clock signal CLK and the complementary signal CLKB of the clock signal CLK toggle, the first output signal OUT and the second output signal OUTB may swing in a normal range. Even when the frequency of the clock signal CLK increases, the reset circuit 210 may maintain the reliability of the clocked latch circuit 200.

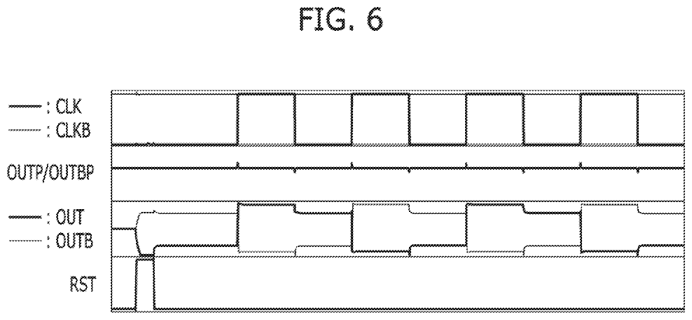

FIG. 6 is a timing diagram, illustrating waveforms of an output signal that is generated from a clocked latch circuit in accordance with an embodiment and an output signal that is generated from a conventional clocked latch circuit. Referring to FIG. 6, it may be difficult for the conventional clocked latch circuit to operate in a wide frequency range. Conventionally, in order for a clocked latch circuit to operate based on a clock signal with a high frequency, sizes of transistors configuring a latch circuit should be decreased. When the sizes of the transistors are decreased, a response to the clock signal with a high frequency may be good but sufficient amplification operation and latch operation might not be performed based on a clock signal with a low frequency. Conversely, when the sizes of the transistors configuring the latch circuit are increased, a response to the clock signal with a low frequency may be good but sufficient amplification operation and latch operation might not be performed based on a clock signal with a high frequency. The conventional clocked latch circuit with a latch circuit, which is configured by transistors of decreased sizes for a good response to a clock signal with a high frequency, might not change the voltage levels of the first output signal OUTP and the second output signal OUTBP to voltage levels that correspond to input signals or might not sufficiently maintain the voltage levels of the first output signal OUTP and the second output signal OUTBP based on the clock signal CLK and the complementary signal CLKB of the clock signal CLK, which have a low frequency. In accordance with an embodiment, the clocked latch circuit 200 may change the amount of the second current ILAT for activating the latch circuit 120 without change of the sizes of transistors configuring the latch circuit 120. When variously changing the second current ILAT without change of the sizes of transistors configuring the latch circuit 120, the clocked latch circuit 200 may generate the first output signal OUT and the second output signal OUTB, which swing in a sufficient range even though the clocked latch circuit 200 receives the clock signal CLK with a low frequency as well as a high frequency. Therefore, the clocked latch circuit 200 may operate in a wider frequency range than a conventional clocked latch circuit and thus, may be utilized in various systems. Further, because of the reset circuit 210 configured to set the initial voltage levels of the first output signal OUT and the second output signal OUTB based on the reset signal RST, the reliability and the operational frequency range of the clocked latch circuit 200 may be improved.

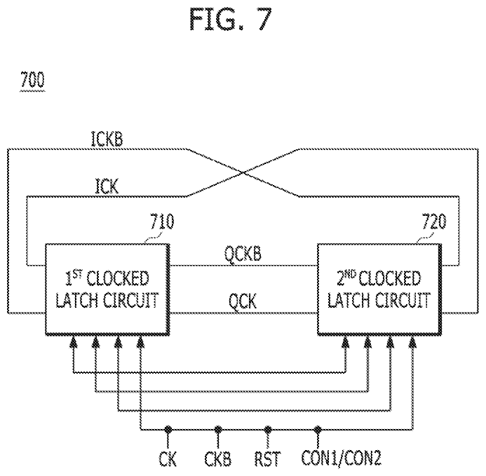

FIG. 7 is a diagram, illustrating a configuration of a clock generating circuit 700 in accordance with an embodiment. Referring to FIG. 7, the clock generating circuit 700 may include a first clocked latch circuit 710 and a second clocked latch circuit 720. Each of the first clocked latch circuit 710 and the second clocked latch circuit 720 may receive a first control clock signal CK and a second control clock signal CKB. The first clocked latch circuit 710 and the second clocked latch circuit 720 may operate in synchronization with the first control clock signal CK and the second control clock signal CKB, respectively. The first clocked latch circuit 710 may receive a first clock signal ICK and a third clock signal ICKB to output a second clock signal QCK and a fourth clock signal QCKB. The first clocked latch circuit 710 may differentially amplify the first clock signal ICK and the third clock signal ICKB to change the voltage levels of the second clock signal QCK and the fourth clock signal QCKB and may latch the voltage levels of the second clock signal QCK and the fourth clock signal QCKB. For example, when the second control clock signal CKB is enabled, the first clocked latch circuit 710 may differentially amplify the first clock signal ICK and the third clock signal ICKB to change the voltage levels of the second clock signal QCK and the fourth clock signal QCKB. When the first control clock signal CK is enabled, the first clocked latch circuit 710 may latch the voltage levels of the second clock signal QCK and the fourth clock signal QCKB. The second control clock signal CKB may be a complementary signal of the first control clock signal CK. Logic high level sections of the first control clock signal CK and the second control clock signal CKB might not overlap with each other. The first clocked latch circuit 710 may differentially amplify the first clock signal ICK and the third clock signal ICKB to generate the second clock signal QCK and the fourth clock signal QCKB during the logic high level section of the second control clock signal CKB. The first clocked latch circuit 710 may maintain the voltage levels of the second clock signal QCK and the fourth clock signal QCKB during the logic high level section of the first control clock signal CK.

The second clocked latch circuit 720 may receive the second clock signal QCK and the fourth clock signal QCKB to output the first clock signal ICK and the third clock signal ICKB. The second clocked latch circuit 720 may differentially amplify the second clock signal QCK and the fourth clock signal QCKB to change the voltage levels of the first clock signal ICK and the third clock signal ICKB and may latch the voltage levels of the first clock signal ICK and the third clock signal ICKB. For example, the second clocked latch circuit 720 may perform an opposite operation to the first clocked latch circuit 710. When the first control clock signal CK is enabled, the second clocked latch circuit 720 may differentially amplify the second clock signal QCK and the fourth clock signal QCKB to change the voltage levels of the first clock signal ICK and the third clock signal ICKB. When the second control clock signal CKB is enabled, the second clocked latch circuit 720 may latch the voltage levels of the first clock signal ICK and the third clock signal ICKB. The second clocked latch circuit 720 may differentially amplify the second clock signal QCK and the fourth clock signal QCKB to change the voltage levels of the first clock signal ICK and the third clock signal ICKB during the logic high level section of the first control clock signal CK. The second clocked latch circuit 720 may maintain the voltage levels of the first clock signal ICK and the third clock signal ICKB during the logic high level section of the second control clock signal CKB.

The frequency of the first to fourth clock signals ICK, QCK, ICKB and QCKB may be half of the frequency of the first control clock signal CK and the second control clock signal CKB. The period of the first to fourth clock signals ICK, QCK, ICKB and QCKB may be double the period of the first control clock signal CK and the second control clock signal CKB. Therefore, the clock generating circuit 700 may function as a frequency dividing circuit. The second clock signal QCK may have a lagging phase to the first clock signal ICK by 90 degrees. The third clock signal ICKB may have a lagging phase to the second clock signal QCK by 90 degrees. The fourth clock signal QCKB may have a lagging phase to the third clock signal ICKB by 90 degrees. The first clock signal ICK may have a lagging phase to the fourth clock signal QCKB by 90 degrees. The first clocked latch circuit 710 and the second clocked latch circuit 720 may configure a chain structure in which input/output nodes of the first clocked latch circuit 710 and the second clocked latch circuit 720 are coupled to each other, to continuously generate the first to fourth clock signals ICK, ICKB, QCK and QCKB toggling with a half frequency of and/or a double period of the first control clock signal CK and the second control clock signal CKB while the first control clock signal CK and the second control clock signal CKB are provided. The clocked latch circuit 100 and the clocked latch circuit 200, illustrated in FIGS. 1 and 2, may be applied as the first clocked latch circuit 710 and the second clocked latch circuit 720.

Each of the first clocked latch circuit 710 and the second clocked latch circuit 720 may further receive the reset signal RST. The first clocked latch circuit 710 may change the voltage levels of the second clock signal QCK and the fourth clock signal QCKB based on the first control clock signal CK, the second control clock signal CKB and the reset signal RST. When the reset signal RST is enabled, the first clocked latch circuit 710 may set the initial voltage levels of the second clock signal QCK and the fourth clock signal QCKB based on the logic levels of the first control clock signal CK and the second control clock signal CKB. The second clocked latch circuit 720 may change the voltage levels of the first clock signal ICK and the third clock signal ICKB based on the first control clock signal CK, the second control clock signal CKB and the reset signal RST. When the reset signal RST is enabled, the second clocked latch circuit 720 may set the initial voltage levels of the first clock signal ICK and the third clock signal ICKB based on the logic levels of the first control clock signal CK and the second control clock signal CKB.

Each of the first clocked latch circuit 710 and the second clocked latch circuit 720 may further receive a first current control signal CON1 and a second current control signal CON2. The first current control signal CON1 may change the current amount of a current source that is configured to activate an amplification circuit that is configured to differentially amplify the first clock signal ICK and the third clock signal ICKB within the first clocked latch circuit 710. The first current control signal CON1 may change the current amount of a current source that is configured to activate an amplification circuit that is configured to differentially amplify the second clock signal QCK and the fourth clock signal QCKB within the second clocked latch circuit 720. The second current control signal CON2 may change the current amount of a current source that is configured to activate a latch circuit that is configured to latch the voltage levels of the second clock signal QCK and the fourth clock signal QCKB within the first clocked latch circuit 710. The second current control signal CON2 may change the current amount of a current source that is configured to activate a latch circuit that is configured to latch the voltage levels of the first clock signal ICK and the third clock signal ICKB within the second clocked latch circuit 720.

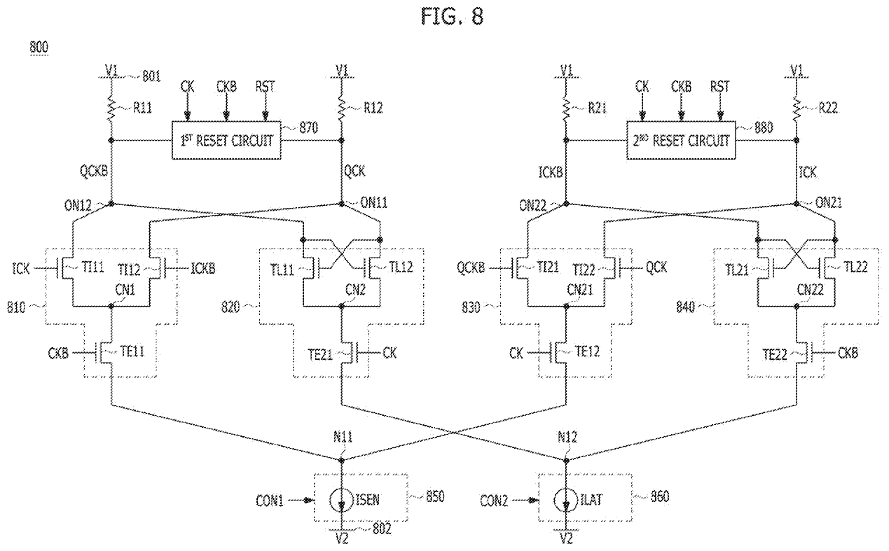

FIG. 8 is a diagram, illustrating a configuration of a clock generating circuit 800 in accordance with an embodiment. Referring to FIG. 8, the clock generating circuit 800 may include a first amplification circuit 810, a first latch circuit 820, a second amplification circuit 830, a second latch circuit 840, a first current source 850, and a second current source 860. The first amplification circuit 810 and the second amplification circuit 830 may be coupled commonly to the first current source 850. The first latch circuit 820 and the second latch circuit 840 may be coupled commonly to the second current source 860. The first amplification circuit 810 may be activated based on the second control clock signal CKB. In synchronization with the second control clock signal CKB, the first amplification circuit 810 may differentially amplify the first clock signal ICK and the third clock signal ICKB to generate the second clock signal QCK and the fourth clock signal QCKB. The first amplification circuit 810 may be coupled to a first output node ON11, a second output node ON12 and a first node N11. The first output node ON11 and the second output node ON12 may be coupled to a node 801 to which the first power voltage V1 is supplied. The second clock signal QCK may be output from the first output node ON11, and the fourth clock signal QCKB may be output from the second output node ON12. The second output node ON12 may be coupled to the node 801 to which the first power voltage V1 is supplied through a first load resistor R11. The first output node ON11 may be coupled to the node 801 to which the first power voltage V1 is supplied through a second load resistor R12. The first load resistor R11 and the second load resistor R12 may have the same resistance value. In an embodiment, the second load resistor R12 may have a different resistance value than the first load resistor R11. When the second control clock signal CKB is enabled, the first amplification circuit 810 may change the voltage levels of the first output node ON11 and the second output node ON12 based on the first clock signal ICK and the third clock signal ICKB. The first amplification circuit 810 may change the voltage level(s) of the second output node ON12 and/or the fourth clock signal QCKB based on the first clock signal ICK. The first amplification circuit 810 may change the voltage level(s) of the first output node ON11 and/or the second clock signal QCK based on the third clock signal ICKB.

The first latch circuit 820 may be activated based on the first control clock signal CK. The first latch circuit 820 may maintain the voltage levels of the first output node ON11 and the second output node ON12 based on the first control clock signal CK. The first latch circuit 820 may be coupled to the first output node ON11, the second output node ON12, and a second node N12. When the first control clock signal CK is enabled, the first latch circuit 820 may latch the voltage levels of the first output node ON11 and the second output node ON12. The first latch circuit 820 may maintain the voltage level(s) of the first output node ON11 and/or the second clock signal QCK based on the voltage level(s) of the second output node ON12 and/or the fourth clock signal QCKB. The first latch circuit 820 may maintain the voltage level(s) of the second output node ON12 and/or the fourth clock signal QCKB based on the voltage level(s) of the first output node ON11 and/or the second clock signal QCK.

The second amplification circuit 830 may be activated based on the first control clock signal CK. In synchronization with the first control clock signal CK, the second amplification circuit 830 may differentially amplify the second clock signal QCK and the fourth clock signal QCKB to generate the first clock signal ICK and the third clock signal ICKB. The second amplification circuit 830 may be coupled to a third output node ON21, a fourth output node ON22, and the first node N11. The third output node ON21 and the fourth output node ON22 may be coupled to the node 801 to which the first power voltage V1 is supplied. The first clock signal ICK may be output from the third output node ON21 and the third clock signal ICKB may be output from the fourth output node ON22. The fourth output node ON22 may be coupled to the node 801 to which the first power voltage V1 is supplied through a third load resistor R21. The third output node ON21 may be coupled to the node 801 to which the first power voltage V1 is supplied through a fourth load resistor R22. The third load resistor R21 and the fourth load resistor R22 may have the same resistance value. In an embodiment, the fourth load resistor R22 may have a different resistance value than the third load resistor R21. The resistance values of the third load resistor R21 and the fourth load resistor R22 may be the same as the first load resistor R11 and the second load resistor R12, respectively. In an embodiment, the third load resistor R21 and the fourth load resistor R22 may have different resistance values than the first load resistor R11 and the second load resistor R12. When the first control clock signal CK is enabled, the second amplification circuit 830 may change the voltage levels of the third output node ON21 and the fourth output node ON22 based on the second clock signal QCK and the fourth clock signal QCKB. The second amplification circuit 830 may change the voltage level(s) of the fourth output node ON22 and/or the third clock signal ICKB based on the fourth clock signal QCKB. The second amplification circuit 830 may change the voltage level(s) of the third output node ON21 and/or the first clock signal ICK based on the second clock signal QCK.

The second latch circuit 840 may be activated based on the second control clock signal CKB. The second latch circuit 840 may maintain the voltage levels of the third output node ON21 and the fourth output node ON22 based on the second control clock signal CKB. The second latch circuit 840 may be coupled to the third output node ON21, the fourth output node ON22 and the second node N12. When the second control clock signal CKB is enabled, the second latch circuit 840 may latch the voltage levels of the third output node ON21 and the fourth output node ON22. The second latch circuit 840 may maintain the voltage level(s) of the third output node ON21 and/or the first clock signal ICK based on the voltage level(s) of the fourth output node ON22 and/or the third clock signal ICKB. The second latch circuit 840 may maintain the voltage level(s) of the fourth output node ON22 and/or the third clock signal ICKB based on the voltage level(s) of the third output node ON21 and/or the first clock signal ICK.

The first current source 850 may allow a first current ISEN to flow through the first node N11. The first current source 850 may be coupled between the first node N11 and a node 802 to which a second power voltage V2 is supplied. The first current source 850 may allow the first current ISEN to flow from the first node N11 to the node 102 to which the second power voltage V2 is supplied. The first current source 850 may further receive the first current control signal CON1. The first current source 850 may variously change an amount of the first current ISEN based on the first current control signal CON1.

The second current source 860 may allow a second current ILAT to flow through the second node N12. The second current source 860 may be coupled between the second node N12 and the node 802 to which a second power voltage V2 is supplied. The second current source 860 may allow the second current ILAT to flow from the second node N12 to the node 102 to which the second power voltage V2 is supplied. The second current ILAT may be different from the first current ISEN. In an embodiment, the second current ILAT may be greater than the first current ISEN. The second current source 860 may further receive the second current control signal CON2. The second current source 860 may variously change an amount of the second current ILAT based on the second current control signal CON2.

The clock generating circuit 800 may further include a first reset circuit 870 and a second reset circuit 880. The first reset circuit 870 may be coupled between the first output node ON11 and the second output node ON12. The first reset circuit 870 may receive the first control clock signal CK, the second control clock signal CKB, and the reset signal RST. The first reset circuit 870 may change the voltage levels of the first output node ON11 and the second output node ON12 based on the first control clock signal CK, the second control clock signal CKB, and the reset signal RST. When the reset signal RST is enabled, the first reset circuit 870 may set the initial voltage levels of the first output node ON11 and the second output node ON12. The second reset circuit 880 may be coupled between the third output node ON21 and the fourth output node ON22. The second reset circuit 880 may receive the first control clock signal CK, the second control clock signal CKB, and the reset signal RST. The second reset circuit 880 may change the voltage levels of the third output node ON21 and the fourth output node ON22 based on the first control clock signal CK, the second control clock signal CKB, and the reset signal RST. When the reset signal RST is enabled, the second reset circuit 880 may set the initial voltage levels of the third output node ON21 and the fourth output node ON22. Each of the first reset circuit 870 and the second reset circuit 880 may include at least one of the reset circuits 300A and 300B, illustrated in FIGS. 3 and 4.

The first amplification circuit 810 may include a first input transistor TI11, a second input transistor TI12, and a first enable transistor TE11. Each of the first input transistor TI11, the second input transistor TI12, and the first enable transistor TE11 may be a N-channel MOS transistor. The first input transistor TI11 may be coupled to the second output node ON12 and a first common node CN11 at its drain and source, respectively, and may receive the first clock signal ICK at its gate. The second input transistor TI12 may be coupled to the first output node ON11 and the first common node CN11 at its drain and source, respectively, and may receive the third clock signal ICKB at its gate. The first enable transistor TE11 may be coupled between the first common node CN11 and the first node N11 and may receive the second control clock signal CKB at its gate.

The first latch circuit 820 may include a first latch transistor TL11, a second latch transistor TL12, and a second enable transistor TE21. Each of the first latch transistor TL11, the second latch transistor TL12 and the second enable transistor TE21 may be a N-channel MOS transistor. The first latch transistor TL11 may be coupled to the second output node ON12 and a second common node CN12 at its drain and source, respectively, and may be coupled to the first output node ON11 at its gate to receive the second clock signal QCK. The second latch transistor TL12 may be coupled to the first output node ON11 and the second common node CN12 at its drain and source, respectively, and may be coupled to the second output node ON12 at its gate to receive the fourth clock signal QCKB. The second enable transistor TE21 may be coupled between the second common node CN12 and the second node N12 and may receive the first control clock signal CK at its gate.

The second amplification circuit 830 may include a third input transistor TI21, a fourth input transistor TI22, and a third enable transistor TE12. Each of the third input transistor T121, the fourth input transistor TI22 and the third enable transistor TE12 may be a N-channel MOS transistor. The third input transistor T121 may be coupled to the fourth output node ON22 and a third common node CN21 at its drain and source, respectively, and may receive the fourth clock signal QCKB at its gate. The fourth input transistor TI22 may be coupled to the third output node ON21 and the third common node CN21 at its drain and source, respectively, and may receive the second clock signal QCK at its gate. The third enable transistor TE12 may be coupled between the third common node CN21 and the first node N11 and may receive the first control clock signal CK at its gate.

The second latch circuit 840 may include a third latch transistor TL21, a fourth latch transistor TL22, and a fourth enable transistor TE22. Each of the third latch transistor TL21, the fourth latch transistor TL22, and the fourth enable transistor TE22 may be a N-channel MOS transistor. The third latch transistor TL21 may be coupled to the fourth output node ON22 and a fourth common node CN22 at its drain and source, respectively, and may be coupled to the third output node ON21 at its gate to receive the first clock signal ICK. The fourth latch transistor TL22 may be coupled to the third output node ON21 and the fourth common node CN22 at its drain and source, respectively, and may be coupled to the fourth output node ON22 at its gate to receive the third clock signal ICKB. The fourth enable transistor TE22 may be coupled between the fourth common node CN22 and the second node N12 and may receive the second control clock signal CKB at its gate.

In an embodiment, the first amplification circuit 810 may be configured by the first input transistor TI11 and the second input transistor TI12 and the second amplification circuit 830 may be configured by the third input transistor TI21 and the fourth input transistor TI22. The first enable transistor TE11, the third enable transistor TE12, and the first current source 850 may be combined to configure a first activation circuit. The first activation circuit may activate one of the first amplification circuit 810 and the second amplification circuit 830 based on the first control clock signal CK and the second control clock signal CKB. The first activation circuit may be coupled to the first common node CN11, the third common node CN21 and the node 802 to which the second power voltage V2 is supplied. When the second control clock signal CKB is enabled, the first activation circuit may allow the first current ISEN to flow from the first common node CN11 to the node 802 to which the second power voltage V2 is supplied. When the first control clock signal CK is enabled, the first activation circuit may allow the first current ISEN to flow from the third common node CN21 to the node 802 to which the second power voltage V2 is supplied.

In an embodiment, the first latch circuit 820 may be configured by the first latch transistor TL11 and the second latch transistor TL12 and the second latch circuit 840 may be configured by the third latch transistor TL21 and the fourth latch transistor TL22. The second enable transistor TE21, the fourth enable transistor TE22 and the second current source 860 may be combined to configure a second activation circuit. The second activation circuit may activate one of the first latch circuit 820 and the second latch circuit 840 based on the first control clock signal CK and the second control clock signal CKB. The second activation circuit may be coupled to the second common node CN12, the fourth common node CN22 and the node 802 to which the second power voltage V2 is supplied. When the first control clock signal CK is enabled, the second activation circuit may allow the second current ILAT to flow from the second common node CN12 to the node 802 to which the second power voltage V2 is supplied. When the second control clock signal CKB is enabled, the second activation circuit may allow the second current ILAT to flow from the fourth common node CN22 to the node 802 to which the second power voltage V2 is supplied.

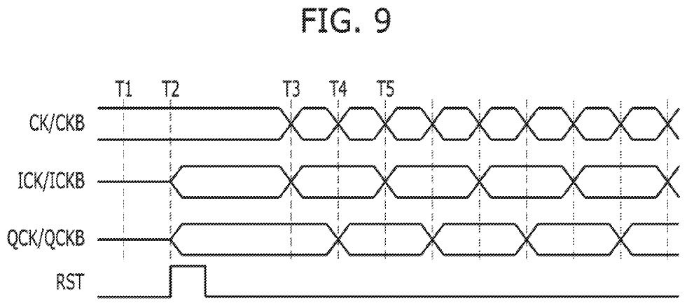

FIG. 9 is a timing diagram, illustrating an operation of a clock generating circuit in accordance with an embodiment. Hereinafter, described with reference to FIGS. 8 and 9 will be the operation of the clock generating circuit 800. While the first control clock signal CK and the second control clock signal CKB toggle, the clock generating circuit 800 may generate the first to fourth clock signals ICK, QCK, ICKB and QCKB. At a time point T1, the clock generating circuit 800 may stay deactivated since the first control clock signal CK may stay fixed to have a logic low level, and the second control clock signal CKB may stay fixed to have a logic high level. At this timing, the voltage levels of the first to fourth clock signals ICK, QCK, ICKB and QCKB might not be defined. The reset signal RST may be enabled for setting the initial voltage levels of the first to fourth clock signals ICK, QCK, ICKB and QCKB. At a time point T2 when the reset signal RST is enabled, the first clock signal ICK and the second clock signal QCK may be set to have a logic low level and the third clock signal ICKB and the fourth clock signal QCKB may be set to have a logic high level. When the first control clock signal CK and the second control clock signal CKB start toggling, the clock generating circuit 800 may generate the first to fourth clock signals ICK, QCK, ICKB, and QCKB in synchronization with the first control clock signal CK and the second control clock signal CKB. At a time point T3 when the first control clock signal CK transitions to a logic high level and the second control clock signal CKB transitions to a logic low level, the first latch circuit 820 and the second amplification circuit 830 may be activated. The first latch circuit 820 may maintain the second clock signal QCK at a logic low level and may maintain the fourth clock signal QCKB at a logic high level. The second amplification circuit 830 may make the third clock signal ICKB transition to a logic low level based on the fourth clock signal QCKB of a logic high level. The second amplification circuit 830 may make the first clock signal ICK transition to a logic high level based on the second clock signal QCK of a logic low level. At a time point T4 when the first control clock signal CK transitions to a logic low level and the second control clock signal CKB transitions to a logic high level, the first amplification circuit 810 and the second latch circuit 840 may be activated, and the first latch circuit 820 and the second amplification circuit 830 may be deactivated. The first amplification circuit 810 may make the fourth clock signal QCKB transition to a logic low level based on the first clock signal ICK of a logic high level. The first amplification circuit 810 may make the second clock signal QCK transition to a logic high level based on the third clock signal ICKB of a logic low level. The second latch circuit 840 may maintain the first clock signal ICK at a logic high level and may maintain the third clock signal ICKB at a logic low level. At a time point T5 when the first control clock signal CK transitions back to a logic high level and the second control clock signal CKB transitions back to a logic low level, the first latch circuit 820 and the second amplification circuit 830 may be activated, and the first amplification circuit 810 and the second latch circuit 840 may be deactivated. The first latch circuit 820 may maintain the second clock signal QCK at a logic high level and may maintain the fourth clock signal QCKB at a logic low level. The second amplification circuit 830 may make the third clock signal ICKB transition to a logic high level based on the fourth clock signal QCKB of a logic low level. The second amplification circuit 830 may make the first clock signal ICK transition to a logic low level based on the second clock signal QCK of a logic high level. After that, whenever the first control clock signal CK and the second control clock signal CKB toggle, a pair of the first amplification circuit 810 and the second latch circuit 840 and a pair of the second amplification circuit 830 and the first latch circuit 820 may alternately operate to generate the first to fourth clock signals ICK, QCK, ICKB and QCKB with a lower frequency than the first control clock signal CK and the second control clock signal CKB. Therefore, the clock generating circuit 800 may function as a frequency division circuit configured to divide the frequency of the first control clock signal CK and the second control clock signal CKB to generate the first to fourth clock signals ICK, QCK, ICKB, and QCKB.

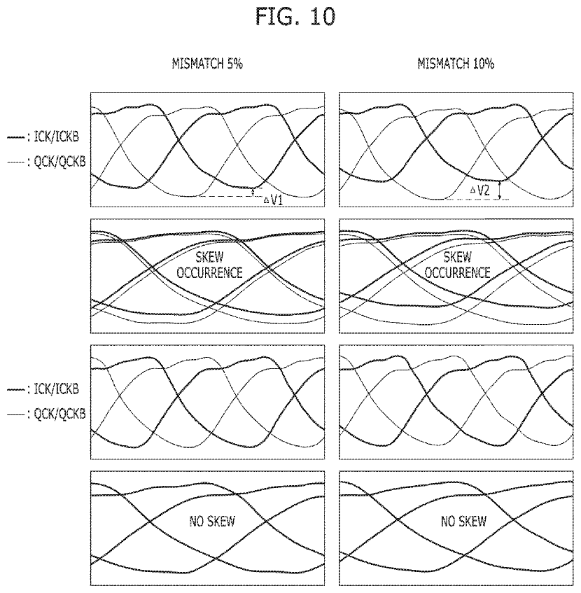

FIG. 10 is a timing diagram, illustrating waveforms of an output signal, generated from a clock generating circuit, in accordance with an embodiment and an output signal, generated from a conventional clock generating circuit. In the conventional clock generating circuit with a first clocked latch circuit and a second clocked latch circuit, an amplification circuit and a latch circuit are commonly coupled to a current source within the first clocked latch circuit and another amplification circuit, and another latch circuit are commonly coupled to another current source within the second clocked latch circuit. When a mismatch occurs between the two current sources, a voltage difference of ‘ΔV1’ occurs between the swing ranges of a second clock signal QCKP and a fourth clock signal QCKBP that are output from the first clocked latch circuit and a first clock signal ICKP and a third clock signal ICKBP that is output from the second clocked latch circuit, and a skew occurs between a pair of the first clock signal ICKP and the third clock signal ICKBP and a pair of the second clock signal QCKP and the fourth clock signal QCKBP. When the mismatch between the two current sources becomes greater from 5% to 10%, the voltage difference between the swing ranges of the second clock signal QCKP and the fourth clock signal QCKBP and the first clock signal ICKP and the third clock signal ICKBP increases from ‘ΔV1’ to ‘ΔV2’, and the skew between the pair of the first clock signal ICKP and the third clock signal ICKBP and the pair of the second clock signal QCKP and the fourth clock signal QCKBP becomes greater. However, in accordance with an embodiment, the first amplification circuit 810 and the second amplification circuit 830 may be commonly coupled to the first current source 850 and the first latch circuit 820 and the second latch circuit 840 may be commonly coupled to the second current source 860, within the clock generating circuit 800. Therefore, even when a mismatch occurs between the first current source 850 and the second current source 860, the swing range of the second clock signal QCK and the fourth clock signal QCKB may be the same as the swing range of the first clock signal ICK and the third clock signal ICKB. Even when a mismatch occurs between the first current source 850 and the second current source 860, the clock generating circuit 800 may prevent skew among the first to fourth clock signals ICK, QCK, ICKB and QCKB.

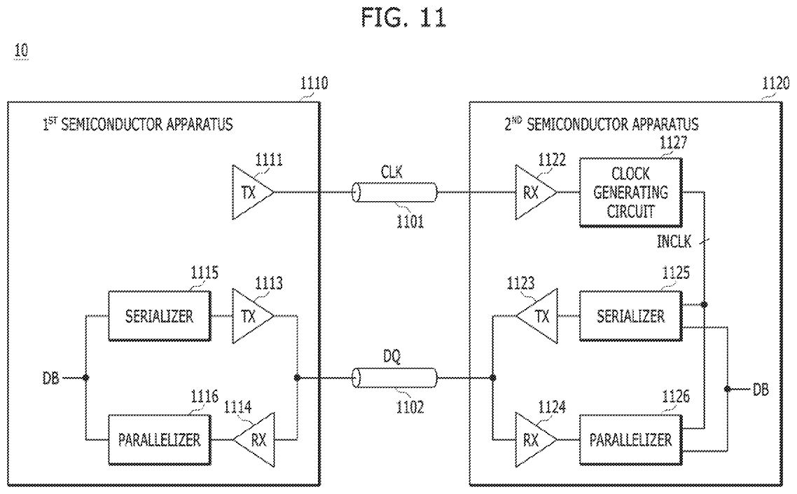

FIG. 11 is a diagram, illustrating a configuration of a semiconductor system 10 in accordance with an embodiment. Referring to FIG. 11, the semiconductor system 10 may include a first semiconductor apparatus 1110 and a second semiconductor apparatus 1120. The first semiconductor apparatus 1110 may be configured to provide various control signals required for the second semiconductor apparatus 1120 to operate. The first semiconductor apparatus 1110 may be a master device to control the second semiconductor apparatus 1120. For example, the first semiconductor apparatus 1110 may be a host device such as a central processing unit (CPU), a graphic processing unit (GPU), a multi-media processor (MMP), a digital signal processor, an application processor (AP) and a memory controller. The second semiconductor apparatus 1120 may be a slave device configured to perform various operations under the control of the first semiconductor apparatus 1110. For example, the second semiconductor apparatus 1120 may be a memory device and the memory device may include a volatile memory and a non-volatile memory. The volatile memory may include a static random access memory (static RAM: SRAM), a dynamic RAM (DRAM) and a synchronous DRAM (SDRAM). The non-volatile memory may include a read only memory (ROM), a programmable ROM (PROM), an electrically erasable and programmable ROM (EEPROM), an electrically programmable ROM (EPROM), a flash memory, a phase change RAM (PRAM), a magnetic RAM (MRAM), a resistive RAM (RRAM), a ferroelectric RAM (FRAM) and so forth.

The second semiconductor apparatus 1120 may be coupled to the first semiconductor apparatus 1110 through a plurality of buses. The plurality of buses may be a signal transmission path, a link or a channel for transferring a signal. The plurality of buses may include a clock bus 1101 and a data bus 1102. The clock bus 1101 may be a one-way bus and the data bus 1102 may be a two-way bus. The second semiconductor apparatus 1120 may be coupled to the first semiconductor apparatus 1110 through the clock bus 1101. The second semiconductor apparatus 1120 may receive a clock signal CLK through the clock bus 1101. The clock signal CLK may include one or more clock signal pairs. The second semiconductor apparatus 1120 may be coupled to the first semiconductor apparatus 1110 through the data bus 1102. The second semiconductor apparatus 1120 may receive data DQ from the first semiconductor apparatus 1110 through the data bus 1102. The second semiconductor apparatus 1120 may provide data DQ to the first semiconductor apparatus 1110 through the data bus 1102. Although not illustrated, the semiconductor system 10 may further include a command bus and an address bus. The second semiconductor apparatus 1120 may be coupled to the first semiconductor apparatus 1110 through the command bus and the address bus. Each of the command bus and the address bus may be a one-way bus. The first semiconductor apparatus 1110 may provide a command signal to the second semiconductor apparatus 1120 through the command bus. The first semiconductor apparatus 1110 may provide an address signal to the second semiconductor apparatus 1120 through the address bus.

The first semiconductor apparatus 1110 may include a clock transmitter (TX) 1111, a data transmitter (TX) 1113, a data receiver (RX) 1114, a serializer 1115 and a parallelizer 1116. The clock transmitter 1111 may be coupled to the clock bus 1101. The clock transmitter 1111 may output, to the clock bus 1101, the clock signal CLK generated from the first semiconductor apparatus 1110. The first semiconductor apparatus 1110 may include a clock generating circuit such as a phase-locked loop circuit (not illustrated) to generate the clock signal CLK. The first semiconductor apparatus 1110 and the second semiconductor apparatus 1120 may perform serial data communication. The serializer 1115 may serialize internal data DB of the first semiconductor apparatus 1110. The data transmitter 1113 may output, as the data DQ, the serialized data through the data bus 1102. The data receiver 1114 may receive data DQ provided from the second semiconductor apparatus 1120 through the data bus 1102. The parallelizer 1116 may parallelize the data DQ received through the data receiver 1114 to generate internal data DB of the first semiconductor apparatus 1110.

The second semiconductor apparatus 1120 may include a clock receiver (RX) 1122, a clock generating circuit 1127, a data transmitter (TX) 1123, a data receiver (RX) 1124, a serializer 1125 and a parallelizer 1126. The clock receiver 1122 may be coupled to the clock bus 1101. The clock receiver 1122 may receive the clock signal CLK provided from the first semiconductor apparatus 1110 through the clock bus 1101. The clock generating circuit 1127 may receive the clock signal CLK through the clock receiver 1122 to generate a plurality of internal clock signals INCLK. The clock generating circuit 1127 may divide the frequency of the clock signal CLK to generate the plurality of internal clock signals INCLK. According to an embodiment, the plurality of internal clock signals INCLK may have a lower frequency than the clock signal CLK. For example, the frequency of the clock signal CLK may be double the frequency of the plurality of internal clock signals INCLK and the period of the plurality of internal clock signals INCLK may be double the period of the clock signal CLK. The clock generating circuit illustrated in FIG. 5 may be applied as the clock generating circuit 1127. The first to fourth clock signals illustrated in FIG. 5 may correspond to the plurality of internal clock signals INCLK.

In synchronization with the clock signal CLK, the second semiconductor apparatus 1120 may receive the data DQ provided from the first semiconductor apparatus 1110 and may provide the data DQ to the first semiconductor apparatus 1110. In synchronization with the clock signal CLK, the second semiconductor apparatus 1120 may receive and/or sample the data DQ provided through the data bus 1102. The second semiconductor apparatus 1120 may utilize the plurality of internal clock signals INCLK, which are generated through the division of the clock signal CLK, in order to sufficiently secure a timing margin for receiving and/or sampling the data DQ. In the similar way, the second semiconductor apparatus 1120 may provide, in synchronization with the clock signal CLK, the data DQ to the first semiconductor apparatus 1110. The second semiconductor apparatus 1120 may utilize the plurality of internal clock signals INCLK, which are generated through the division of the clock signal CLK, in order to sufficiently secure a timing margin for providing the data DQ. The serializer 1125 may serialize internal data DB of the second semiconductor apparatus 1120. The serializer 1125 may serialize the internal data DB of the second semiconductor apparatus 1120 in synchronization with the plurality of internal clock signals INCLK. The data transmitter 1123 may output, as the data DQ, the serialized data through the data bus 1102. The data receiver 1124 may receive data DQ provided from the first semiconductor apparatus 1110 through the data bus 1102. The parallelizer 1126 may parallelize the data DQ received through the data receiver 1124. In synchronization with the plurality of internal clock signals INCLK, the parallelizer 1126 may parallelize the data DQ received through the data receiver 1124 to generate the internal data DB of the second semiconductor apparatus 1120.

While certain embodiments have been described above, it will be understood to those skilled in the art that the embodiments described are by way of example only. Accordingly, the clocked latch circuit and a clock generating circuit using the same should not be limited based on the described embodiments. Rather, the clocked latch circuit and a clock generating circuit using the same described herein should only be limited in light of the claims that follow when taken in conjunction with the above description and accompanying drawings.

What is claimed is:

1. A clocked latch circuit comprising:
an amplification circuit coupled to a first output node, a second output node, and a first node and configured to change voltage levels of the first output node and the second output node based on a clock signal, a first input signal, and a second input signal, wherein the first output node and the second output node are coupled to a node to which a first power voltage is supplied;
a latch circuit coupled to the first output node, the second output node, and a second node and configured to maintain the voltage levels of the first output node and the second output node based on a complementary signal of the clock signal;
a first current source configured to allow a first current to flow from the first node to a node to which a second power voltage is supplied; and
a second current source configured to allow a second current to flow from the second node to the node to which the second power voltage is supplied,
wherein the second current is different from the first current.

2. The clocked latch circuit of claim 1,
wherein the second input signal is one of a complementary signal with a complementary voltage level to the first input signal and a reference voltage, and
wherein the reference voltage has a voltage level that corresponds to a middle of a range in which the first input signal swings.

3. The clocked latch circuit of claim 1, wherein the amplification circuit includes:
a first input transistor configured to couple the second output node to a first common node based on the first input signal;
a second input transistor configured to couple the first output node to the first common node based on the second input signal; and
a first enable transistor configured to couple the first common node to the first node based on the clock signal.

4. The clocked latch circuit of claim 1, wherein the latch circuit includes:
a first latch transistor configured to couple the first output node to a second common node based on the voltage level of the second output node;
a second latch transistor configured to couple the second output node to the second common node based on the voltage level of the first output node; and
a second enable transistor configured to couple the second common node and the second node based on the complementary signal of the clock signal.

5. The clocked latch circuit of claim 1, wherein the second current is greater than the first current.

6. The clocked latch circuit of claim 1,
wherein the first current source changes an amount of the first current based on a first current control signal, and
wherein the second current source changes an amount of the second current based on a second current control signal.

7. The clocked latch circuit of claim 1, further comprising a reset circuit coupled to the first output node, the second output node and the node to which the second power voltage is supplied, and configured to change the voltage levels of the first output node and the second output node based on a reset signal, the clock signal and the complementary signal of the clock signal.

8. A clocked latch circuit comprising:
an amplification circuit coupled between a first common node and a node to which a first power voltage is supplied and configured to change voltage levels of a first output node and a second output node based on a first input signal and a second input signal;
a latch circuit coupled between a second common node and the node to which the first power voltage is supplied and configured to maintain the voltage levels of the first output node and the second output node based on the voltage levels of the first output node and the second output node;
a first activation circuit configured to allow a first current to flow from the first common node to a node to which a second power voltage is supplied based on a clock signal; and
a second activation circuit configured to allow a second current to flow from the second common node to the node to which the second power voltage is supplied based on the clock signal,
wherein the second current is different from the first current.

9. The clocked latch circuit of claim 8,
wherein the second input signal is one of a complementary signal with a complementary voltage level to the first input signal and a reference voltage, and
wherein the reference voltage has a voltage level that corresponds to a middle of a range in which the first input signal swings.

10. The clocked latch circuit of claim 8, wherein the amplification circuit includes:
a first input transistor configured to couple the second output node to the first common node based on the first input signal; and
a second input transistor configured to couple the first output node to the first common node based on the second input signal.

11. The clocked latch circuit of claim 8, wherein the first activation circuit includes:
a first enable transistor configured to couple the first common node to a first node based on the clock signal; and
a first current source configured to output the first current to flow from the first node to the node to which the second power voltage is supplied.

12. The clocked latch circuit of claim 8, wherein the latch circuit includes:
a first latch transistor configured to couple the second output node to the second common node based on the voltage level of the first output node; and
a second latch transistor configured to couple the first output node to the second common node based on the voltage level of the second output node.

13. The clocked latch circuit of claim 8, wherein the second activation circuit includes:
a second enable transistor configured to couple the second common node to a second node based on the clock signal; and
a second current source configured to output the second current to flow from the second node to the node to which the second power voltage is supplied.

14. The clocked latch circuit of claim 8, wherein the second current is greater than the first current.

15. The clocked latch circuit of claim 8,
wherein the first activation circuit changes an amount of the first current based on a first current control signal, and
wherein the second activation circuit changes an amount of the second current based on a second current control signal.

16. The clocked latch circuit of claim 8, further comprising a reset circuit coupled to the first output node, the second output node, and the node to which the second power voltage is supplied and configured to change the voltage levels of the first output node and the second output node based on a reset signal, the clock signal, and a complementary signal of the clock signal.

17. A clock generating circuit comprising:
a first amplification circuit coupled between a first node and a node to which a first power voltage is supplied and configured to output a second clock signal and a fourth clock signal through a first output node and a second output node based on a first control clock signal, a first clock signal, and a third clock signal;
a first latch circuit coupled between a second node and the node to which the first power voltage is supplied and configured to maintain voltage levels of the first output node and the second output node based on a second control clock signal;
a second amplification circuit coupled between the first node and the node to which the first power voltage is supplied and configured to output the first clock signal and the third clock signal through a third output node and a fourth output node based on the second control clock signal, the second clock signal, and the fourth clock signal;
a second latch circuit coupled between the second node and the node to which the first power voltage is supplied and the second node and configured to maintain voltage levels of the third output node and the fourth output node based on the first control clock signal;
a first current source configured to allow a first current to flow from the first node to a node to which a second power voltage is supplied; and
a second current source configured to allow a second current to flow from the second node to the node to which the second power voltage is supplied,
wherein the second current is different from the first current.

18. The clock generating circuit of claim 17, wherein the second current is greater than the first current.

19. The clock generating circuit of claim 17,
wherein the first current source changes an amount of the first current based on a first current control signal, and
wherein the second current source changes an amount of the second current based on a second current control signal.

20. A clock generating circuit comprising:
a first amplification circuit coupled between a first common node and a node to which a first power voltage is supplied and configured to output a second clock signal and a fourth clock signal through a first output node and a second output node based on a first clock signal and a third clock signal;
a first latch circuit coupled between a second common node and the node to which the first power voltage is supplied and configured to maintain voltage levels of the first output node and the second output node;
a second amplification circuit coupled between a third common node and the node to which the first power voltage is supplied and configured to output the first clock signal and the third clock signal through a third output node and a fourth output node based on the second clock signal and the fourth clock signal;
a second latch circuit coupled between a fourth common node and the node to which the first power voltage is supplied and configured to maintain voltage levels of the third output node and the fourth output node;
a first activation circuit configured to output a first current to flow from the first common node to a node to which a second power voltage is supplied based on a first control clock signal and configured to output the first current to flow from the third common node to the node to which the second power voltage is supplied based on a second control clock signal; and
a second activation circuit configured to allow a second current to flow from the second common node to the node to which the second power voltage is supplied based on the second control clock signal and configured to allow the second current to flow from the fourth common node to the node to which the second power voltage is supplied based on the first control clock signal.

21. The clock generating circuit of claim 20, wherein the second current is greater than the first current.

22. The clock generating circuit of claim 20,
wherein the first activation circuit changes an amount of the first current based on a first current control signal, and
wherein the second activation circuit changes an amount of the second current based on a second current control signal.
